(19) United States
(12) Patent Application Publication
(10) Pub. No.: US 2017/0082923 A1
(43) Pub. Date: Mar. 23, 2017

(54) PHOTOSENSITIVE COMPOSITION FOR PERMANENT FILMS, RESIST MATERIAL AND COATING FILM

(71) Applicant: DIC Corporation, Tokyo (JP)

(72) Inventors: Tomoyuki Imada, Ichihara-shi (JP); Seiji Kimoto, Ichihara-shi (JP); Yusuke Sato, Ichihara-shi (JP)

(21) Appl. No.: 15/309,271

(22) PCT Filed: May 19, 2015
(86) PCT No.: PCT/JP2015/064265

§ 371 Date: Nov. 7, 2016

(30) Foreign Application Priority Data
Jun. 12, 2014 (JP) 2014-121532

(51) Int. Cl. G03F 7/039; G03F 7/20; G03F 7/16; G03F 7/32; C08G 8/26; C08G 8/12

(52) U.S. Cl. CPC G03F 7/039; C08G 8/26; C08G 8/12; G03F 7/162; G03F 7/168; G03F 7/322; G03F 7/2002

(57) ABSTRACT

A photosensitive composition for permanent films having a hydroxynaphthalene novolac resin having a structural portion (I) represented by Formula (1) as a repeating unit and containing a hydroxynaphthalene (A) represented by Formula (2) in an amount of 2% by mass or less of the solid content of the resin, and which does not contain a curing agent, or contains a curing agent of 50 parts by mass or less to 100 parts by mass of the resin. In the formulas, R¹ represents a hydrogen atom, an alkyl group, an alkoxy group, an aryl group, an aralkyl group, or a halogen atom, a plurality of R¹ may be the same as or different from each other, R² represents a hydrogen atom, an alkyl group, or an aryl group, p represents 1 or 2, and q represents 4 or 5, with the proviso that the sum of p and q is 6.

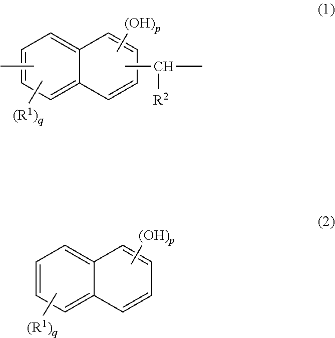

### TECHNICAL FIELD

The present invention relates to a photosensitive composition which has high photosensitivity and resolution, and excellent heat resistance and moisture absorption resistance, and is used as a material for forming permanent films insusceptible to contamination even in high temperature environments, a resist material thereof, and a coating film thereof.

### BACKGROUND ART

A compound containing a phenolic hydroxyl group has been widely used in electrical and electronic fields such as a semiconductor sealing material or a printed circuit board insulating material, as a curable resin composition which has a compound containing a phenolic hydroxyl group per se as the main agent or as a curing agent for an epoxy resin or the like, from the viewpoint of the fact that the resultant cured product has excellent heat resistance and moisture resistance, in addition to being used for adhesives, molding materials, paint, photoresist materials, epoxy resin raw materials, or curing agents for epoxy resins.

In addition, coating films formed of a photosensitive composition of a photoresist material or the like are also used as members which are collectively referred to as conceptually a permanent film. A permanent film is a coating film formed of a photosensitive composition formed on the parts or between the parts configuring a product in mainly semiconductor devices such as an IC and an LSI or display devices such as a thin display, and also remains even after completion of the product.

As a resist material used for permanent films, a negative type resist material using a (meth)acrylic acid ester-based polymer is widely used, and to improve hardness and heat resistance, a method of dispersing silica, a pigment, or the like in a photocurable polymer solution is generally used. However, due to proximity of a display unit and a light source due to miniaturization and thinning of recent display elements, with a negative type resist material formed of a (meth)acrylic acid ester-based polymer in the related art, it becomes difficult to achieve both fining and heat resistance. For the purpose of solving this problem, for example, in PTL 1, a chemical amplification type positive photosensitive thermosetting resin composition including a reaction product of an alkali soluble resin with a crosslinking polyvinyl ether compound, a photoacid generator, and an epoxy resin, as materials of a permanent film has been proposed. In addition, in PTL 2, it is disclosed that a positive photosensitive adhesive composition containing an alkali soluble resin having a phenolic hydroxyl group or a carboxyl group, a compound having a quinonediazide group, and a crosslinking agent is used as a material of permanent films.

### CITATION LIST

### Patent Literature

[PTL 1] JP-A-2005-181976

[PTL 2] JP-A-2009-244663

### SUMMARY OF INVENTION

### Technical Problem

In the permanent film formed of the photosensitive composition described in PTL 1 or 2, in the product having gaps between the members, distortion occurs due to moisture absorption of the moisture present in the air or an expansion difference during heating between a member side and a gap side due to the presence of a gap in some cases.

In addition, in the resin components contained in these photosensitive compositions, the amount of unreacted monomer components mixed in is large. Thus, in high temperature environments, there is a problem that the monomer components sublimated from the permanent film adhere to and contaminate the permanent film and the members therearound.

Therefore, an object of the present invention is to provide a photosensitive composition which has excellent photosensitivity, resolution, heat resistance, and moisture absorption resistance, is insusceptible to contamination in high temperature environments, and suitable as a material for permanent films, a resist material, and a coating film thereof.

### Solution to Problem

As a result of intensive studies to solve the above problems, the present inventors found that a hydroxynaphthalene novolac resin obtained by reaction in the presence of an acid catalyst in a system containing a specific organic solvent and a specific amount of water such that the molar ratio of hydroxynaphthalenes is within a range of 0.5 to 1.5 with respect to aldehydes has excellent photosensitivity, resolution, heat resistance, and moisture absorption resistance, and has a very small residual amount of unreacted hydroxynaphthalenes, and thus, the hydroxynaphthalene novolac resin is insusceptible to contamination in high temperature environments, and suitable as a material for permanent films, and thus completed the present invention.

That is, the present invention relates to a photosensitive composition for permanent films which contains a hydroxynaphthalene novolac resin having a structural portion (I) represented by the following General Formula (1) as a repeating unit and containing a hydroxynaphthalene (A) represented by the following General Formula (2) in an amount of 2% by mass or less in terms of the solid content of the resin, and which does not contain a curing agent, or contains a curing agent in an amount of 50 parts by mass or less with respect to 100 parts by mass of the hydroxynaphthalene novolac resin.

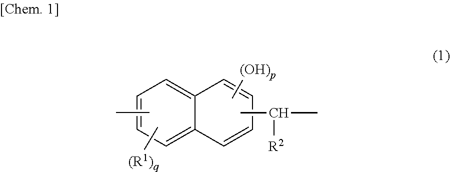

In General Formula (1), R¹ represents a hydrogen atom, an alkyl group, an alkoxy group, an aryl group which may have a substituent, an aralkyl group which may have a substituent, or a halogen atom, a plurality of R¹'s may be the same as or different from each other, R² represents a hydrogen atom, an alkyl group which may have a substituent, or aryl group which may have a substituent, p represents 1 or 2, and q represents 4 or 5, with the proviso that the sum of p and q is 6.

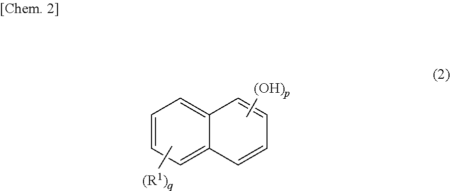

In General Formula (2), each of R¹, p, and q is as defined in General Formula (1).

The present invention further relates to a resist material formed of the photosensitive composition for permanent films and a coating film formed of the photosensitive composition for permanent films.

### Advantageous Effects of Invention

Since the photosensitive composition for permanent films according to the present invention contains the hydroxynaphthalene novolac resin obtained from hydroxynaphthalenes and aldehydes, the photosensitive composition has excellent photosensitivity, resolution, heat resistance, and moisture absorption resistance. Additionally, the amount of hydroxynaphthalenes mixed in is very small, and thus, even in high temperature environments, a probability that the hydroxynaphthalene will be sublimated from the coating film is low, and the peripheral region is less likely to be contaminated. Thus, it is possible to provide a permanent film having excellent heat resistance, moisture absorption resistance, and contamination resistance with the photosensitive composition for permanent films according to the present invention.

### BRIEF DESCRIPTION OF DRAWINGS

FIG. 1 is a GPC chart of a novolac resin (1) obtained in Synthesis Example 1.

FIG. 2 is a GPC chart of a novolac resin (2) obtained in Synthesis Example 2.

FIG. 3 is a GPC chart of a novolac resin (3) obtained in Synthesis Example 3.

FIG. 4 is a GPC chart of a novolac resin (4) obtained in Synthesis Example 4.

FIG. 5 is a GPC chart of a novolac resin (5) obtained in Synthesis Example 5.

### DESCRIPTION OF EMBODIMENTS

The photosensitive composition for permanent films according to the present invention contains a hydroxynaphthalene novolac resin having a structural portion (I) represented by the following General Formula (1) as a repeating unit (referred to as “a hydroxynaphthalene novolac resin according to the present invention” in some cases). By having a hydroxynaphthalene novolac resin structure as the main skeleton, a photosensitive composition capable of forming a resist coating film having photosensitivity, resolution, and alkali developing properties, and heat resistance and moisture absorption resistance which are difficult to be achieved at the same time in the related art can be obtained.

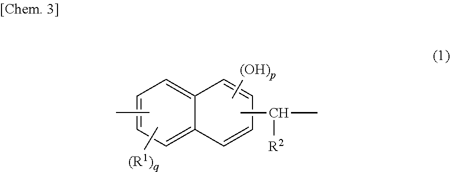

In General Formula (1), p represents 1 or 2, and q represents 4 or 5, with the proviso that the sum of p and q is 6. That is, in the case where p is 1, q is 5, and in the case where p is 2, q is 4.

In the structural portion (I) represented by General Formula (1), the substitution position of the phenolic hydroxyl groups on the naphthylene skeleton is arbitrary. Among these, from the viewpoint of the fact that the resin having excellent resolution and heat resistance can be obtained, in the case where p is 1, the substitution position of the phenolic hydroxyl group is preferably a 1 position, and in the case where p is 2, the substitution position of the phenolic hydroxyl group is preferably a 2 or 7 position.

In General Formula (1), R¹ represents a hydrogen atom, an alkyl group, an alkoxy group, an aryl group which may have a substituent, an aralkyl group which may have a substituent, or a halogen atom. In addition, four or five R¹'s are present in General Formula (1), and the plurality of R¹'s may be the same as or different from each other.

In the case where R¹ in General Formula (1) is an alkyl group, the alkyl group may be linear, branched, or may be a group having a cyclic structure, and is preferably a linear group. In the present invention, in the case where R¹ is an alkyl group, R¹ is preferably an alkyl group having 1 to 12 carbon atoms, more preferably an alkyl group having 1 to 8 carbon atoms, and still more preferably an alkyl group having 1 to 6 carbon atoms. Specifically, examples of the alkyl group include a methyl group, an ethyl group, a propyl group, an isopropyl group, a n-butyl group, an isobutyl group, a t-butyl group, a pentyl group, an isoamyl group, a hexyl group, a cyclohexyl group, a heptyl group, a cyclohexylmethyl group, an octyl group, a cyclohexylethyl group, a nonyl group, a decyl group, an adamantyl group, a undecyl group, an adamantylmethyl group, a dodecyl group, and an adamantylethyl group, and a methyl group, an ethyl group, a propyl group, an isopropyl group, a n-butyl group, an isobutyl group, a t-butyl group, a pentyl group, an isoamyl group, a hexyl group, or a cyclohexyl group is preferable.

In the case where R¹ in General Formula (1) is an alkoxy group, the alkyl group portion in the alkoxy group may be linear, branched, or may be a group having a cyclic structure, and is preferably a linear group. In the present invention, in the case where R¹ is an alkoxy group, R¹ is preferably an alkoxy group having 1 to 12 carbon atoms, more preferably an alkoxy group having 1 to 8 carbon atoms, and still more preferably an alkoxy group having 1 to 6 carbon atoms. Specifically, examples of the alkoxy group include a methoxy group, an ethoxy group, a propyloxy group, an isopropyloxy group, a n-butyloxy group, an isobutyloxy group, a t-butyloxy group, a pentyloxy group, an isoamyloxy group, a hexyloxy group, a cyclohexyloxy group, a heptyloxy group, an octyloxy group, a nonyloxy group, a decyloxy group, a undecyloxy group, and a dodecyloxy group, and a methoxy group, an ethoxy group, a propyloxy group, a butyloxy group, a pentyloxy group, a hexyloxy group, or a cyclohexyloxy group is preferable.

In the case where R¹ in General Formula (1) is an aryl group which may have a substituent, examples of the aryl group include a phenyl group, a naphthyl group, an indenyl group, and a biphenyl group. In addition, the hydrogen atoms in the aryl group may be substituted with a substituent, and examples of the substituent include a hydroxyl group, an alkyl group having 1 to 6 carbon atoms, and an alkoxy group having 1 to 6 carbon atoms. The number of the substituents which the aryl group has is not particularly limited, and the number is preferably 1 to 3, and more preferably 1 or 2. In addition, in the case where one aryl group has a plurality of substituents, respective substituents may be the same as or different from each other. Specifically, examples of the aryl group which may have a substituent include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, and a dihydroxynaphthyl group, and a phenyl group is preferable.

In the case where R¹ in General Formula (1) is an aralkyl group which may have a substituent, examples of the aryl group portion in the aralkyl group include a phenyl group, a naphthyl group, an indenyl group, and a biphenyl group, and a phenyl group is preferable. In addition, the alkyl group portion in the aralkyl group may be linear, branched, or may be a group having a cyclic structure, and is preferably a linear group, more preferably an alkyl group having 1 to 6 carbon atoms, and still more preferably a linear or branched alkyl group having 1 to 6 carbon atoms. The hydrogen atom in the aryl group in the aralkyl group may be substituted with a substituent, and examples of the type and number of the substituent include the same type and number of the substituent as those exemplified as the substituent which the aryl group may have. Specifically, examples of the aralkyl group which may have a substituent include a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, and a dihydroxynaphthylethyl group, and a phenylmethyl group, a hydroxyphenylmethyl group, or a dihydroxyphenylmethyl group is preferable.

In the case where R¹ in General Formula (1) is a halogen atom, examples of the halogen atom include a fluorine atom, a chlorine atom, and a bromine atom.

As the structural portion (I) represented by General Formula (1), R¹ is preferably a hydrogen atom, an alkyl group, or an alkoxy group, all of R¹'s are more preferably hydrogen atoms or alkyl groups since a resin becomes excellent in heat resistance and water absorbency resistance, all of R¹ are still more preferably hydrogen atoms, methyl groups, ethyl groups, propyl groups, isopropyl groups, n-butyl groups, isobutyl groups, t-butyl groups, pentyl groups, isoamyl groups, hexyl groups, or cyclohexyl groups, all of R¹ are still more preferably hydrogen atoms, methyl groups, ethyl groups, propyl groups, isopropyl groups, n-butyl groups, isobutyl groups, or t-butyl groups, and all of R¹ are particularly preferably hydrogen atoms.

In General Formula (1), R² represents a hydrogen atom, an alkyl group which may have a substituent, or an aryl group which may have a substituent.

In the case where R² in General Formula (1) is an alkyl group which may have a substituent, the alkyl group may be linear, branched, or may be a group having a cyclic structure, and is preferably a linear group. In the present invention, in the case where R² is an alkyl group, R² is preferably an alkyl group having 1 to 12 carbon atoms, more preferably an alkyl group having 1 to 8 carbon atoms, and still more preferably an alkyl group having 1 to 6 carbon atoms.

In the case where R² in General Formula (1) is an alkyl group, the hydrogen atom in the alkyl group may be substituted by a substituent. Examples of the substituent include a hydroxyl group, an alkoxy group having 1 to 6 carbon atoms, an aryl group which may have a substituent, and a halogen atom. Examples of the alkoxy group and the aryl group having 1 to 6 carbon atoms include the same alkoxy group and aryl group as the alkoxy group and the aryl group capable of being taken by R¹ respectively. The number of the hydrogen atoms that may be substituted is not particularly limited, and the number is preferably 1 to 3, and more preferably 1 or 2. In addition, in the case where one alkyl group has a plurality of substituents, respective substituents may be the same as or different from each other. Specifically, examples of the alkyl group represented by R² include a methyl group, an ethyl group, a propyl group, an isopropyl group, a n-butyl group, an isobutyl group, a t-butyl group, a pentyl group, an isoamyl group, a hexyl group, a cyclohexyl group, a hydroxyethyl group, a hydroxypropyl group, a fluoromethyl group, a methoxyethyl group, an ethoxyethyl group, a methoxypropyl group, a phenylmethyl group, a hydroxyphenylmethyl group, a dihydroxyphenylmethyl group, a tolylmethyl group, a xylylmethyl group, a naphthylmethyl group, a hydroxynaphthylmethyl group, a dihydroxynaphthylmethyl group, a phenylethyl group, a hydroxyphenylethyl group, a dihydroxyphenylethyl group, a tolylethyl group, a xylylethyl group, a naphthylethyl group, a hydroxynaphthylethyl group, and a dihydroxynaphthylethyl group, and a methyl group, an ethyl group, a propyl group, an isopropyl group, a n-butyl group, an isobutyl group, a t-butyl group, a pentyl group, an isoamyl group, a hexyl group, or a cyclohexyl group is preferable.

In the case where R² in General Formula (1) is an aryl group which may have a substituent, examples of the aryl group include a phenyl group, a naphthyl group, an indenyl group, and a biphenyl group. In addition, the hydrogen atoms in the aryl group may be substituted by a substituent. Examples of the substituent include a hydroxyl group, an alkoxy group having 1 to 6 carbon atoms, an aryl group, and a halogen atom. Examples of the alkoxy group and the aryl group having 1 to 6 carbon atoms include the same alkoxy group and aryl group as the alkoxy group and the aryl group capable of being taken by R¹ respectively. The number of the hydrogen atoms that may be substituted is not particularly limited, and the number is preferably 1 to 3, and more preferably 1 or 2. In addition, in the case where one aryl group has a plurality of substituents, respective substituents may be the same as or different from each other. Specifically, examples of the aryl group represented by R² which may have a substituent include a phenyl group, a hydroxyphenyl group, a dihydroxyphenyl group, a hydroxyalkoxyphenyl group, an alkoxyphenyl group, a tolyl group, a xylyl group, a naphthyl group, a hydroxynaphthyl group, a dihydroxynaphthyl group, and a bromophenyl group.

As the structural portion (I) represented by General Formula (1), from the viewpoint of the fact that a hydroxynaphthalene novolac resin having high dry etching resistance and resistance to thermal decomposition and a photosensitive composition having high sensitivity and resolution can be obtained, R² is preferably an aryl group which may have a substituent, and more preferably an aryl group containing a hydroxyl group such as a hydroxyphenyl group, a dihydroxyphenyl group, a hydroxyalkoxyphenyl group, a hydroxynaphthyl group, or a dihydroxynaphthyl group.

As the structural portion (I) represented by General Formula (1), it is preferable that all of R¹'s are hydrogen atoms, alkyl groups, or alkoxy groups, and R² is a hydrogen atom or an aryl group which may have a substituent, it is more preferable that all of R¹'s are hydrogen atoms, methyl groups, ethyl groups, propyl groups, isopropyl groups, n-butyl groups, isobutyl groups, t-butyl groups, pentyl groups, isoamyl groups, hexyl groups, or cyclohexyl groups, and R² is a hydrogen atom or an aryl group containing a hydroxyl group, and it is still more preferable that all of R¹'s are hydrogen atoms, methyl groups, ethyl groups, propyl groups, isopropyl groups, n-butyl groups, isobutyl groups, or t-butyl groups, and R² is a hydrogen atom, a hydroxyphenyl group, a dihydroxyphenyl group, a hydroxyalkoxyphenyl group, a hydroxynaphthyl group, or a dihydroxynaphthyl group.

The hydroxynaphthalene novolac resin according to the present invention is obtained by reacting the hydroxynaphthalene (A) represented by the following General Formula (2) with the aldehyde (B) represented by the following General Formula (3). In General Formula (2), R¹, p, and q are the same as those in General Formula (1), and in General Formula (3), R² is the same as that in General Formula (1).

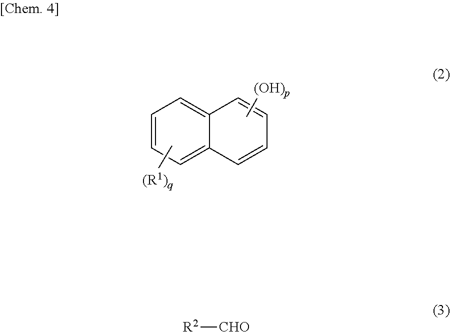

In the hydroxynaphthalene novolac resin according to the present invention, the content of the hydroxynaphthalene (A) is 2% by mass or less in terms of the solid content of the resin. The unreacted hydroxynaphthalene (A) more easily sublimates than the resin component does, and thus, in a thin film such as a coating film formed of a resin in which the amount of the hydroxynaphthalenes (A) mixed in is large, in high temperature environments, the hydroxynaphthalene (A) sublimated from the coating film coagulates on the coating film surface or the member surface near that and is contaminated. In contrast, in the coating film of the photosensitive composition which has the hydroxynaphthalene novolac resin according to the present invention as a main component, the amount of unreacted hydroxynaphthalene (A) mixed in is small, and thus, there is almost no hydroxynaphthalene (A) which sublimates even in high temperature environments, and contamination of the coating film surface or the surrounding thereof is less likely to occur. The content of the hydroxynaphthalene (A) in the hydroxynaphthalene novolac resin according to the present invention is preferably 1.5% by mass or less, and more preferably 1.2% by mass or less, in terms of the solid content of the resin.

The content of the hydroxynaphthalene (A) in the hydroxynaphthalene novolac resin according to the present invention can be determined by gas chromatography (GC). Specifically, for each hydroxynaphthalene used as a raw material, the content is calculated from the area% of the GC peaks on the basis of the calibration curve prepared using a specimen of which the concentration is known.

The weight average molecular weight (Mw) of the hydroxynaphthalene novolac resin according to the present invention is preferably within a range of 1,000 to 8,000 from the viewpoint of the fact that a resin having high resolution, and excellent heat resistance and moisture absorption resistance is obtained. In addition, the value of polydispersity (Mw/Mn) is preferably within a range of 1.2 to 2.3 from the viewpoint of the fact that a resin having high resolution, and excellent heat resistance and moisture absorption resistance is obtained.

The weight average molecular weight (Mw) and the polydispersity (Mw/Mn) of the hydroxynaphthalene novolac resin according to the present invention are values measured by gel permeation chromatography (GPC). Measurement conditions of GPC are as described in the examples described below.

The hydroxynaphthalene novolac resin according to the present invention is, for example, obtained by reacting the hydroxynaphthalene (A) represented by General Formula (2) with the aldehyde (B) represented by General Formula (3) in a mixed solvent of a hydrophobic organic solvent and water under acid catalyst conditions.

The hydroxynaphthalenes (A) are not particularly limited as long as they are represented by General Formula (2), and examples thereof include 1-naphthol, 2-naphthol, 1,4-dihydroxynaphthalene, 1,5-dihydroxynaphthalene, 1,6-dihydroxynaphthalene, 2,6-dihydroxynaphthalene, 2,7-dihydroxynaphthalene, and compounds in which these aromatic nuclei have been substituted with one to plural alkyl groups, alkoxy groups, aryl groups, or aralkyl groups, or halogen atoms, 1-naphthol, 2-naphthol, 1,4-dihydroxynaphthalene, 1,5-dihydroxynaphthalene, 1,6-dihydroxynaphthalene, 2,3-dihydroxynaphthalene, or 2,7-dihydroxynaphthalene is preferable, and 2,7-dihydroxynaphthalene is particularly preferable. The hydroxynaphthalenes (A) used as a raw material may be one type of compound, or may be used in combination of two or more compounds.

In the production of the hydroxynaphthalene novolac resin according to the present invention, a compound having an aromatic hydroxyl group other than the hydroxynaphthalene (A) can be used in combination within a range not impairing the effects of the present invention. Examples of the compound having an aromatic hydroxyl group include phenols. Examples of the phenols include phenol, cresol, xylenol, butylphenol, and phenylphenol. In the case where a compound having an aromatic hydroxyl group other than the hydroxynaphthalene (A) is used in combination, the amount used is preferably 0.1 to 10 parts by mass with respect to 100 parts by mass of the hydroxynaphthalene (A).

The aldehyde (B) is not particularly limited as long as they are represented by General Formula (3), and among these, formaldehyde (HCOH); alkyl aldehydes such as acetaldehyde, propylaldehyde, butyraldehyde, isobutyraldehyde, pentyl aldehyde, and hexyl aldehyde; hydroxybenzaldehydes such as salicylaldehyde, 3-hydroxybenzaldehyde, 4-hydroxybenzaldehyde, 2-hydroxy-4-methylbenzaldehyde, 2,4-dihydroxybenzaldehyde, and 3,4-dihydroxybenzaldehyde; benzaldehydes having both a hydroxyl group and an alkoxy group such as 2-hydroxy-3-methoxybenzaldehyde, 3-hydroxy-4-methoxybenzaldehyde, 4-hydroxy-3-methoxybenzaldehyde, 3-ethoxy-4-hydroxybenzaldehyde, and 4-hydroxy-3,5-dimethoxybenzaldehyde; alkoxybenzaldehydes such as methoxybenzaldehyde and ethoxybenzaldehyde; hydroxynaphthaldehydes such as 1-hydroxy-2-naphthaldehyde, 2-hydroxy-1-naphthaldehyde, and 6-hydroxy-2-naphthaldehyde; or halogenated benzaldehydes such as bromobenzaldehyde are preferable, formaldehyde, 4-hydroxy-3-methoxybenzaldehyde, 3-ethoxy-4-hydroxybenzaldehyde, salicylaldehyde, 3-hydroxybenzaldehyde, 4-hydroxybenzaldehyde, or 2,4-dihydroxybenzaldehyde is more preferable, and formaldehyde, salicylaldehyde, 3-hydroxybenzaldehyde, or 4-hydroxybenzaldehyde is still more preferable. The aldehyde (B) used as a raw material may be one type of compound, or may be used in combination of two or more compounds.

In the case where the aldehyde (B) used as a raw material is formaldehyde, as the raw material, an aqueous solution of formaldehyde (formalin), paraformaldehyde, or trioxane is also preferably used.

From the viewpoint of the fact that a hydroxynaphthalene novolac resin is efficiently generated, the reaction is preferably performed under the condition where the reaction proportion [(A)/(B)] of the hydroxynaphthalene (A) to the aldehyde (B) is within a range of 0.5 to 1.5 in the molar ratio. If the reaction proportion of the hydroxynaphthalene (A) to the aldehyde (B) is within the above range, it is possible to reduce the amount of the unreacted hydroxynaphthalene (A) remaining in the obtained hydroxynaphthalene novolac resin.

A reaction of the hydroxynaphthalene (A) with the aldehyde (B) is performed in a mixed solvent of water and an organic solvent. Examples of the organic solvent used in the reaction include alcohols such as propanol, butanol, octanol, ethylene glycol, glycerin, ethylene glycol monomethyl ether, ethylene glycol monoethyl ether, ethylene glycol monobutyl ether, and propylene glycol monomethyl ether; ketones such as methyl ethyl ketone and methyl isobutyl ketone; and esters such as butyl acetate, ethylene glycol monomethyl ether acetate, ethylene glycol monoethyl ether acetate, and propylene glycol monomethyl ether acetate. The organic solvent used in the reaction may be formed of one type, or may be a mixed solvent of two or more types. Among these, one or more selected from the group consisting of butanol, octanol, methyl ethyl ketone, and methyl isobutyl ketone are preferably used, and methyl isobutyl ketone is more preferably used from the viewpoint of separativeness of an aqueous layer and an organic layer.

As the use proportion of the organic solvent in the mixed solvent used in the reaction, an organic solvent of 50 to 500 parts by mass with respect to 100 parts by mass of the hydroxynaphthalenes (A) is preferable for the reasons why the reaction rate is sufficiently fast and a hydroxynaphthalene novolac resin is efficiently obtained and the time of solvent removal by distillation after production of the hydroxynaphthalene novolac resin becomes a relatively short period of time, and 100 to 500 parts by mass is more preferable.

As the use proportion of water in the mixed solvent used in the reaction, water of 30 to 300 parts by mass is used with respect to 100 parts by mass of the hydroxynaphthalenes (A). If a large amount of water is present in the reaction system, low molecular weight substances regardless of the size of molecular weight and a hydroxynaphthalene novolac resin in which the residual amount of residual monomer (hydroxynaphthalenes (A)) is small are obtained. The amount of water in the reaction system is more preferably 35 to 250 parts by mass with respect to 100 parts by mass of the hydroxynaphthalenes (A).

Examples of the acid catalyst used in the reaction include inorganic acids such as sulfuric acid, hydrochloric acid, nitric acid, hydrobromic acid, perchloric acid, and phosphoric acid, sulfonic acids such as p-toluenesulfonic acid, methanesulfonic acid, and benzenesulfonic acid, organic acids such as oxalic acid, succinic acid, malonic acid, monochloroacetic acid, and dichloroacetic acid, and Lewis acids such as boron trifluoride, anhydrous aluminum chloride, and zinc chloride. Among these, since p-toluenesulfonic acid shows strong acidity and promotes the reaction of the hydroxynaphthalene (A) with the aldehyde (B) at high activity, p-toluenesulfonic acid is preferable. The amount of these acid catalysts used is preferably within a range of 0.1% to 25% by mass with respect to the total mass of the reaction raw materials.

The temperature conditions when reacting the hydroxynaphthalene (A) with the aldehyde (B) are preferably within a range of 50° C. to 120° C. from the viewpoint of high reaction efficiency. In particular, in the case where 2,7-dihydroxynaphthalene and formaldehyde are reacted, the reaction is preferably performed at 60° C. to 90° C.

The reaction of the hydroxynaphthalene (A) with the aldehyde (B) can be performed, for example, in the following manner. First, the hydroxynaphthalene (A), an organic solvent, the aldehyde (B), and water are put into a flask provided with a thermometer, a cooling tube, a fractionating column, and a stirrer. After the hydroxynaphthalene (A), an organic solvent, the aldehyde (B), and water are put into the flask, the mixture is stirred. An acid catalyst is added while stirring. The amount of the acid catalyst used is typically 0.01 to 5 parts by mass with respect to 100 parts by mass of the hydroxynaphthalenes (A). An amount greater than the above amount may be used, but since a large amount of alkali is used in the neutralization step, extra time is required, and therefore, the amount may be suitably determined.

By putting the hydroxynaphthalene (A), the aldehyde (B), an organic solvent, and water into the reaction system, the hydroxynaphthalene (A) are dissolved or dispersed in the organic solvent phase, and the aldehyde (B) are dissolved or dispersed in the aqueous phase. Even in the case where the organic solvent phase and the aqueous layer in the reaction system are stirred, these are not “homogeneously” mixed (dissolved), and thus, these are in a “heterogeneous” state. Two layers may form a “heterogeneous” state, a part of the organic layer may be “homogeneously” mixed with the aqueous layer, or a part of the aqueous layer may be “homogeneously” mixed with the organic layer. A part of the hydroxynaphthalene (A) may be dissolved or dispersed in water, or a part of the aldehyde (B) may be dissolved or dispersed in the organic solvent.

Next, after an acid catalyst is added to the reaction system, the temperature of the reaction system is raised. After the reaction temperature is raised, the hydroxynaphthalene (A) and the aldehyde (B) are allowed to react with stirring. The reaction time is typically 0.5 to 10 hours. After the reaction ends, the reaction system is transferred to a separating funnel, and the aqueous layer was separated from the organic layer and removed. Thereafter, the organic layer is washed until the washing liquid becomes neutral. After washing, the organic layer is left to stand while being heated under reduced pressure, thereby removing the organic solvent from the organic layer. Thus, a hydroxynaphthalene novolac resin in which the residual amount of unreacted monomer (hydroxynaphthalenes (A)) is small can be obtained.

The photosensitive composition for permanent films according to the present invention has the hydroxynaphthalene novolac resin according to the present invention as an essential component, and may not contain a curing agent, but if necessary, may contain a curing agent.

Examples of the curing agent used in the present invention include a melamine compound substituted with at least one group selected from a methylol group, an alkoxymethyl group, and an acyloxymethyl group, a guanamine compound, a glycoluril compound, a urea compound, a resole resin, an epoxy compound, an isocyanate compound, an azide compound, a compound including a double bond such as an alkenyl ether group, acid anhydride, and an oxazoline compound.

Examples of the melamine compound include hexamethylolmelamine, hexamethoxymethylmelamine, a compound in which 1 to 6 methylol groups in hexamethylolmelamine have been methoxymethylated, hexamethoxyethylmelamine, hexaacyloxymethylmelamine, and a compound in which 1 to 6 methylol groups in hexamethylolmelamine have been acyloxymethylated.

Examples of the guanamine compound include tetramethylolguanamine, tetramethoxymethylguanamine, tetramethoxymethylbenzoguanamine, a compound in which 1 to methylol groups in tetramethylolguanamine have been methoxymethylated, tetramethoxyethylguanamine, tetraacyloxyguanamine, and a compound in which 1 to 4 methylol groups in tetramethylolguanamine have been acyloxymethylated.

Examples of the glycoluril compound include 1,3,4,6-tetrakis(methoxymethyl)glycoluril, 1,3,4,6-tetrakis(butoxymethyl)glycoluril, and 1,3,4,6-tetrakis(hydroxymethyl)glycoluril.

Examples of the urea compound include 1,3-bis(hydroxymethyl)urea, 1,1,3,3-tetrakis(butoxymethyl)urea, and 1,1,3,3-tetrakis(methoxymethyl)urea.

Examples of the resole resin include alkylphenols such as phenol, cresol, and xylenol, bisphenols such as phenylphenol, resorcinol, biphenyl, bisphenol A, and bisphenol F, and a polymer obtained by reacting a compound containing a phenolic hydroxyl group such as naphthol or dihydroxynaphthalene with an aldehyde compound under alkali catalyst conditions.

Examples of the epoxy compound include tris(2,3-epoxypropyl)isocyanurate, trimethylolmethane triglycidyl ether, trimethylolpropane triglycidyl ether, and triethylolethane triglycidyl ether.

Examples of the isocyanate compound include tolylene diisocyanate, diphenylmethane diisocyanate, hexamethylene diisocyanate, and cyclohexane diisocyanate.

Examples of the azide compound include 1,1′-biphenyl-4,4′-bisazide, 4,4′-methylidenebisazide, and 4,4′-oxybisazide.

Examples of the compound including a double bond such as an alkenyl ether group include ethyleneglycol divinyl ether, triethyleneglycol divinyl ether, 1,2-propanediol divinyl ether, 1,4-butanediol divinyl ether, tetramethyleneglycol divinyl ether, neopentylglycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylolpropane trivinyl ether.

Examples of the acid anhydride include aromatic acid anhydrides such as phthalic anhydride, trimellitic anhydride, pyromellitic anhydride, 3,3′,4,4′-benzophenonetetracarboxylic dianhydride, biphenyltetracarboxylic dianhydride, 4,4′-(isopropylidene)diphthalic anhydride, and 4,4′-(hexafluoro isopropylidene)diphthalic anhydride; and alicyclic carboxylic acid anhydrides such as tetrahydrophthalic anhydride, methyltetrahydrophthalic anhydride, hexahydrophthalic anhydride, methylhexahydrophthalic anhydride, endomethylene tetrahydrophthalic anhydride, dodecenylsuccinic anhydride, and trialkyltetrahydrophthalic anhydride.

Among these, from the viewpoint of the fact that a composition having excellent curability and excellent dry etching resistance and resistance to thermal decomposition in the case of being used for permanent film applications is obtained, a glycoluril compound, a urea compound, or a resole resin is preferable, and a glycoluril compound is particularly preferable.

In the case where the photosensitive composition for permanent films according to the present invention contains the curing agent, the blending amount of curing agent is 50 parts by mass or less with respect to 100 parts by mass of the hydroxynaphthalene novolac resin according to the present invention to maintain excellent alkali developing properties and sensitivity by the hydroxynaphthalene novolac resin according to the present invention. The blending amount of curing agent in the photosensitive composition for permanent films according to the present invention is preferably in a proportion within a range of 0.1 to 50 parts by mass from the viewpoint of the fact that a composition which has excellent curability, heat resistance, and alkali developing properties is obtained, more preferably in a proportion within a range of 0.1 to 30 parts by mass from the viewpoint of the fact that a composition which also has excellent sensitivity is obtained, and still more preferably in a proportion within a range of 0.5 to 20 parts by mass, with respect to 100 parts by mass of the hydroxynaphthalene novolac resin according to the present invention.

The photosensitive composition for permanent films according to the present invention preferably contains a photosensitive agent, in addition to the hydroxynaphthalene novolac resin according to the present invention. As the photosensitive agent, a compound having a quinonediazide group is exemplified. Specific examples of the compound having a quinonediazide group include a complete ester compound of an aromatic (poly)hydroxy compound and sulfonic acid having a quinonediazide group such as naphthoquinone-1,2-diazido-5-sulfonic acid, naphthoquinone-1,2-diazido-4-sulfonic acid, or o-anthraquinonediazidosulfonic acid, a partial ester compound, an amidated product, and a partially amidated product.

Examples of the aromatic (poly)hydroxy compound used here include polyhydroxybenzophenone compounds such as 2,3,4-trihydroxybenzophenone, 2,4,4′-trihydroxybenzophenone, 2,4,6-trihydroxybenzophenone, 2,3,6-trihydroxybenzophenone, 2,3,4-trihydroxy-2′-methylbenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5-pentahydroxybenzophenone, 2,3′,4,4′,5′,6-hexahydroxybenzophenone, and 2,3,3′,4,4′,5′-hexahydroxybenzophenone;

bis[(poly)hydroxyphenyl]alkane compounds such as bis(2,4-dihydroxyphenyl)methane, bis(2,3,4-trihydroxyphenyl)methane, 2-(4-hydroxyphenyl)-2-(4′-hydroxyphenyl)propane, 2-(2,4-dihydroxyphenyl)-2-(2′,4′-dihydroxyphenyl)propane, 2-(2,3,4-trihydroxyphenyl)-2-(2′,3′,4′-trihydroxyphenyl)propane, 4,4′-{1-[4-[2-(4-hydroxyphenyl)-2-propyl]phenyl]ethylidene}bisphenol, and 3,3′-dimethyl-{1-[4-[2-(3-methyl-4-hydroxyphenyl)-2-propyl]phenyl]ethylidene}bisphenol;

tris(hydroxyphenyl)methane compounds such as tris(4-hydroxyphenyl)methane, bis(4-hydroxy-3,5-dimethylphenyl)-4-hydroxyphenyl methane, bis(4-hydroxy-2,5-dimethylphenyl)-4-hydroxyphenyl methane, bis(4-hydroxy-3,5-dimethylphenyl)-2-hydroxyphenyl methane, bis(4-hydroxy-2,5-dimethylphenyl)-2-hydroxyphenyl methane, bis(4-hydroxy-2,5-dimethylphenyl)-3,4-dihydroxyphenyl methane, and bis(4-hydroxy-3,5-dimethylphenyl)-3,4-dihydroxyphenyl methane, and methyl-substituted products thereof;

bis(cyclohexylhydroxyphenyl)(hydroxyphenyl)methane compounds such as bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(5-cyclohexyl-4-hydroxy-2-methylphenyl)-2-hydroxyphenyl methane, bis(5-cyclohexyl-4-hydroxy-2-methylphenyl)-3-hydroxyphenyl methane, bis(5-cyclohexyl-4-hydroxy-2-methylphenyl)-4-hydroxyphenyl methane, bis(3-cyclohexyl-2-hydroxyphenyl)-3-hydroxyphenyl methane, bis(5-cyclohexyl-4-hydroxy-3-methylphenyl)-4-hydroxyphenyl methane, bis(5-cyclohexyl-4-hydroxy-3-methylphenyl)-3-hydroxyphenyl methane, bis(5-cyclohexyl-4-hydroxy-3-methylphenyl)-2-hydroxyphenyl methane, bis(3-cyclohexyl-2-hydroxyphenyl)-4-hydroxyphenyl methane, bis(3-cyclohexyl-2-hydroxyphenyl)-2-hydroxyphenyl methane, bis(5-cyclohexyl-2-hydroxy-4-methylphenyl)-2-hydroxyphenyl methane, and bis(5-cyclohexyl-2-hydroxy-4-methylphenyl)-4-hydroxyphenyl methane, and methyl-substituted products thereof. These photosensitive agents may be used alone respectively, or in combination of two or more types thereof.

The blending amount of photosensitive agent in the photosensitive composition for permanent films according to the present invention is preferably in a proportion within a range of 5 to 50 parts by mass with respect to 100 parts by mass of the hydroxynaphthalene novolac resin according to the present invention from the viewpoint of the fact that a composition having excellent photosensitivity is obtained.

In the photosensitive composition for permanent films according to the present invention, as a resin component, other resins may be used in combination, in addition to the hydroxynaphthalene novolac resin according to the present invention. As other resins, any resin can be used as long as the resin is soluble in an alkali developer, or the resin is dissolved in an alkali developer by using in combination with an additive such as an acid generator.

In the case where other resins are used, the blending ratio of the hydroxynaphthalene novolac resin according to the present invention and other resins can be arbitrarily adjusted depending on the desired application. Among these, since the photosensitivity, the resolution, and the alkali developing properties achieved by the present invention are high, and the excellent effects in heat resistance and moisture absorption resistance are also sufficiently expressed, the hydroxynaphthalene novolac resin according to the present invention is preferably used in an amount of 60% by mass or more, and more preferably used in an amount of 80% by mass or more, with respect to the total amount of the hydroxynaphthalene novolac resin according to the present invention and other resins.

The photosensitive composition for permanent films according to the present invention may contain a surfactant for the purpose of improving the film forming properties or the adhesion of patterns in the case of being used in resist applications, and reducing development defects. Examples of the surfactant used here include nonionic surfactants such as polyoxyethylene alkyl ether compounds including polyoxyethylene lauryl ether, polyoxyethylene stearyl ether, polyoxyethylene cetyl ether, and polyoxyethylene oleyl ether, polyoxyethylene alkyl allyl ether compounds including polyoxyethylene octylphenol ether and polyoxyethylene nonylphenol ether, sorbitan fatty acid ester compounds including a polyoxyethylene-polyoxypropylene block copolymer, sorbitan monolaurate, sorbitan monopalmitate, sorbitan monostearate, sorbitan monooleate, sorbitan trioleate, and sorbitan tristearate, and polyoxyethylene sorbitan fatty acid ester compounds including polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants having a fluorine atom in the molecular structure such as a copolymer of a polymerizable monomer having a fluoroaliphatic group and [poly(oxyalkylene)](meth)acrylate; and silicone surfactants having a silicone structural portion in the molecular structure. These may be used alone respectively, or in combination of two or more types thereof. The blending amount of these surfactants is preferably within a range of 0.001 to 2 parts by mass with respect to 100 parts by mass of the resin solid content in the photosensitive composition for permanent films according to the present invention.

The photosensitive composition for permanent films according to the present invention may further contain a filler. By a filler, it is possible to improve the hardness and the heat resistance of a coating film. The filler contained in the photosensitive composition for permanent films according to the present invention may be an organic filler, but an inorganic filler is preferable. Examples of the inorganic filler include silica, mica, talc, clay, bentonite, montmorillonite, kaolinite, wollastonite, calcium carbonate, calcium hydroxide, magnesium carbonate, titanium oxide, alumina, aluminum hydroxide, barium sulfate, barium titanate, potassium titanate, zinc oxide, and glass fiber. Among these, since the thermal expansion coefficient can be lowered, silica is preferably used.

The photosensitive composition for permanent films according to the present invention is preferably a composition obtained by dissolving and dispersing the hydroxynaphthalene novolac resin according to the present invention, and if necessary, various additives such as other resins, a photosensitive agent, a photoacid generator, an organic base compound, a surfactant, a filler, a dye, a pigment, a crosslinking agent, and a dissolution accelerator in an organic solvent. By applying a composition obtained by dissolving in an organic solvent to a substrate, it is possible to form a coating film. The photoacid generator and the organic base compound can be suitably selected from among those generally used as an additive of a resist material and used, in consideration of the type of resin used or the like.

Examples of the organic solvent include alkylene glycol monoalkyl ethers such as ethylene glycol monomethyl ether, ethylene glycol monoethyl ether, ethylene glycol monopropyl ether, and ethylene glycol monobutyl ether propylene glycol monomethyl ether; dialkylene glycol dialkyl ethers such as diethylene glycol dimethyl ether, diethylene glycol diethyl ether, diethylene glycol dipropyl ether, and diethylene glycol dibutyl ether; alkylene glycol alkyl ether acetates such as ethylene glycol monomethyl ether acetate, ethylene glycol monoethyl ether acetate, and propylene glycol monomethyl ether acetate; ketone compounds such as acetone, methyl ethyl ketone, cyclohexanone, and methyl amyl ketone; cyclic ethers such as dioxane; and ester compounds such as methyl 2-hydroxypropionate, ethyl 2-hydroxypropionate, ethyl 2-hydroxy-2-methylpropionate, ethyl ethoxyacetate, ethyl oxyacetate, methyl 2-hydroxy-3-methylbutanoate, 3-methoxybutyl acetate, 3-methyl-3-methoxybutyl acetate, ethyl formate, ethyl acetate, butyl acetate, methyl acetoacetate, and ethyl acetoacetate, and these may be used alone respectively, or in combination of two or more types thereof.

The photosensitive composition for permanent films according to the present invention can be produced by blending the above-described respective components and mixing these using a stirrer or the like. In addition, in the case where the photosensitive composition contains a filler or a pigment, it is possible to adjust by dispersing or mixing using a dispersing device such as a dissolver, a homogenizer, or a three-roll mill.

The photosensitive composition for permanent films according to the present invention may be used as a resist material. As the photosensitive composition for permanent films according to the present invention, the composition in a state of being dissolved or dispersed in an organic solvent may also be used directly as a resist solution, or one obtained by applying the composition in a state of being dissolved or dispersed in an organic solvent into a film shape and removing the solvent may be used as a resist film. As the support film when used as a resist film, synthetic resin films such as polyethylene, polypropylene, polycarbonate, and polyethylene terephthalate can be exemplified, and the support film may be a single layer film or a plurality of laminated film. In addition, the surface of the support film may be a surface subjected to a corona treatment or coated with a release agent.

In the method of photolithography using the photosensitive composition for permanent films according to the present invention, for example, a photosensitive composition for permanent films dissolved or dispersed in an organic solvent is applied onto an object on which silicon substrate photolithography is performed, and prebaked under a temperature condition of 60° C. to 150° C. The coating method at this time may be any method of spin coating, roll coating, flow coating, dip coating, spray coating, and doctor blade coating. Next, a resist pattern is made, but in the case where the photosensitive composition for permanent films is a positive type, by exposing the target resist pattern through a predetermined mask and by dissolving the exposed portions in an alkali developer, a resist pattern is formed. Since the photosensitive composition for permanent films according to the present invention has high photosensitivity, a resist pattern having excellent resolution can be formed.

A thin film (coating film) formed by applying the photosensitive composition for permanent films according to the present invention is suitable as a permanent film remaining even in the final product after forming a resist pattern if necessary. As specific examples of the permanent film, in the semiconductor devices, package adhesive layers or adhesive layers between an integrated circuit element and a circuit board such as a solder resist, a packaging material, an underfill material, and a circuit element can be exemplified, and in the thin displays represented by LCD and OELD, a thin film transistor protective film, a liquid crystal color filter protective film, a black matrix, and a spacer can be exemplified. In particular, a permanent film formed of the photosensitive composition for permanent films according to the present invention has a very good advantage that released hydroxynaphthalene (A) is very low and contamination properties are low, from the viewpoint of excellent heat resistance and moisture absorption resistance. Thus, in particular, by forming a permanent film from the photosensitive composition for permanent films according to the present invention, it is possible to reduce image quality degradation due to contamination, which is important in a display material, to a minimum. That is, the photosensitive composition for permanent films according to the present invention is a positive type resist material for permanent films which has high sensitivity with low image quality degradation, high heat resistance, and moisture absorption reliability.

### EXAMPLES

Hereinafter, the present invention will be described in more detail with examples, and the present invention is not limited to the examples. Hereinafter, “parts” and “%” are based on mass unless otherwise specifically indicated.

<GPC Measurement of Resin>

The molecular weight distribution of the resin composition was measured under the following measuring conditions by GPC by the polystyrene standard method.

(Measurement Conditions of GPC)

Measuring apparatus: “HLC-8220 GPC” manufactured by Tosoh Corporation,

Column: “Shodex KF802” (8.0 mmφ×300 mm) manufactured by SHOWA DENKO K.K.+“Shodex KF802” (8.0 mmφ×300 mm) manufactured by SHOWA DENKO K.K.+“Shodex KF803” (8.0 mmφ×300 mm) manufactured by SHOWA DENKO K.K.+“Shodex KF804” (8.0 mmφ×300 mm) manufactured by SHOWA DENKO K.K.,

Detector: RI,

Measurement conditions: column temperature 40° C.
eluent: tetrahydrofuran (THF)
flow rate: 1.0 mL/min

Sample: a solution (5 μL) obtained by filtering a tetrahydrofuran solution of 1.0% by mass in terms of the resin solid content through a microfilter,

Standard sample: monodisperse polystyrene of which the molecular weight is known was used.

(Monodisperse Polystyrene)

“A-500” manufactured by Tosoh Corporation

“A-1000” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

“F-40” manufactured by Tosoh Corporation

“F-80” manufactured by Tosoh Corporation

“F-128” manufactured by Tosoh Corporation

“F-288” manufactured by Tosoh Corporation

“F-550” manufactured by Tosoh Corporation

<Measurement of Residual Monomer Amount>

The residual monomer amount in the resin (amount of the unreacted hydroxynaphthalenes) was determined by GC analysis under the following measuring conditions. For each hydroxynaphthalene used as a raw material, a calibration curve was prepared using a standard specimen having a predetermined concentration, and on the basis of the calibration curve, the content of each hydroxynaphthalene was calculated from the area% with respect to the GC peak of the sample.

(Measurement Conditions of GC)

Apparatus: GC-14B manufactured by Shimadzu Corporation

Column: capillary column DB-1 (25 mmφ×60 m)

Column temperature: after being held at 90° C. for one minute, the temperature was raised to 280° C. at 10° C./min, and held for 6 minutes

Temperature of sample vaporization chamber: 250° C.

Detector: FID, 280° C.

Carrier gas: helium

Flow rate: 1.4 mL/min

Sample injection volume: 0.5 μL

### Synthesis Example 1

144 g (1.0 mole) of 1-naphthol, 400 g of methyl isobutyl ketone, 96 g of water, and 27.7 g (0.85 moles) of 92% paraformaldehyde were put into a 1 L four-neck flask provided with a thermometer, a cooling tube, and a stirrer. Subsequently, 4.8 g of an aqueous solution of paratoluenesulfonic acid having a concentration adjusted to 50% was added to the four-neck flask with stirring. The amount of water in the reaction system was 69.9 parts by mass with respect to 100 parts by mass of 1-naphthol.

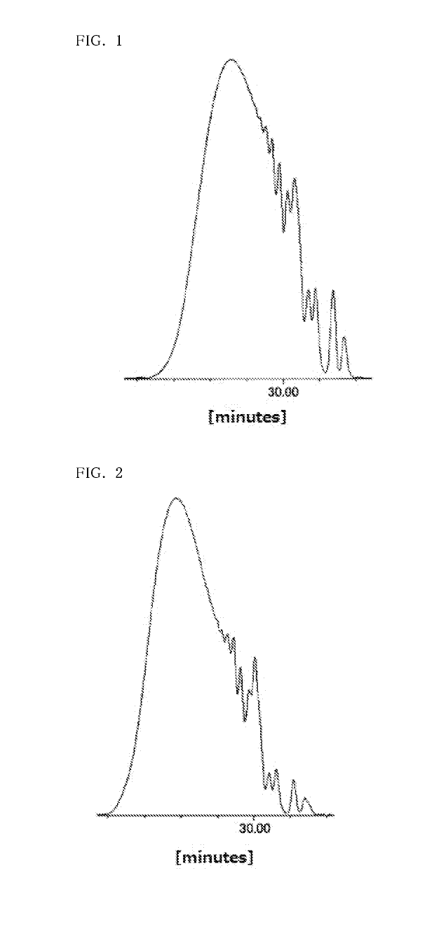

Thereafter, the temperature was raised to 80° C. while stirring the solution in the system, and the solution was allowed to react for 2 hours. During the reaction, the organic layer and the aqueous layer were not in a “homogeneous” state in which the layers were fully compatible, and were in a “heterogeneous” state. After the reaction ended, the solution in the system was transferred to a separating funnel, and the aqueous layer was separated from the organic layer and removed. Next, after washing the resulting product with water until the washing water became neutral, the solvent was removed from the organic layer by heating under reduced pressure, whereby 147 g of a novolac resin (1) was obtained. When GPC and GC were performed on the novolac resin (1), the number average molecular weight (Mn) was 1312, the weight average molecular weight (Mw) was 2251, the polydispersity (Mw/Mn) was 1.716, and the residual monomer amount was 0.57% by mass. The GPC chart of the novolac resin (1) is shown in FIG. 1.

### Synthesis Example 2

144 g (1.0 mole) of 1-naphthol, 2.2 g (0.02 moles) of o-cresol, 400 g of 1-butanol, 96 g of water, and 27.7 g (0.85 moles) of 92% paraformaldehyde were put into a 1 L four-neck flask provided with a thermometer, a cooling tube, and a stirrer. Subsequently, 4.8 g of an aqueous solution of paratoluenesulfonic acid of which the concentration was adjusted to 50% was added to the four-neck flask with stirring. The amount of water in the reaction system was 69.9 parts by mass with respect to 100 parts by mass of 1-naphthol. Thereafter, the temperature was raised to 80° C. while stirring the solution in the system, and the solution was allowed to react for 2 hours. During the reaction, the organic layer and the aqueous layer were not in a “homogeneous” state in which the layers were fully compatible, and were in a “heterogeneous” state. After the reaction ended, the solution in the system was transferred to a separating funnel, and the aqueous layer was separated from the organic layer and removed. Next, after washing the resulting product with water until the washing water became neutral, the solvent was removed from the organic layer by heating under reduced pressure, whereby 147 g of a novolac resin (2) was obtained. When GPC and GC were performed on the novolac resin (2), the number average molecular weight (Mn) was 1765, the weight average molecular weight (Mw) was 3337, the polydispersity (Mw/Mn) was 1.890, and the residual monomer amount was 0.93% by mass. The GPC chart of the novolac resin (2) is shown in FIG. 2.

### Synthesis Example 3

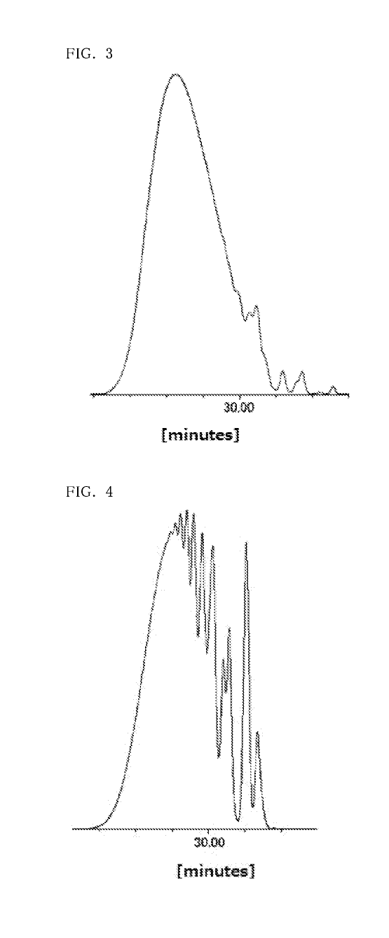

144 g (1.0 mole) of 1-naphthol, 2.2 g (0.02 moles) of o-cresol, 400 g of methyl isobutyl ketone, 96 g of water, and 37.5 g (0.28 moles) of paraaldehyde were put into a 1 L four-neck flask provided with a thermometer, a cooling tube, and a stirrer. Subsequently, 4.8 g of an aqueous solution of paratoluenesulfonic acid having a concentration adjusted to 50% was added to the four-neck flask with stirring. The amount of water in the reaction system was 69.9 parts by mass with respect to 100 parts by mass of 1-naphthol. Thereafter, the temperature was raised to 80° C. while stirring the solution in the system, and the solution was allowed to react for 2 hours. During the reaction, the organic layer and the aqueous layer were not in a “homogeneous” state in which the layers were fully compatible, and were in a “heterogeneous” state. After the reaction ended, the solution in the system was transferred to a separating funnel, and the aqueous layer was separated from the organic layer and removed. Next, after washing the resulting product with water until the washing water became neutral, the solvent was removed from the organic layer by heating under reduced pressure, whereby 152 g of a novolac resin (3) was obtained. When GPC and GC were performed on the novolac resin (3), the number average molecular weight (Mn) was 1694, the weight average molecular weight (Mw) was 2852, the polydispersity (Mw/Mn) was 1.683, and the residual monomer amount was 1.03% by mass. The GPC chart of the novolac resin (3) is shown in FIG. 3.

### Synthesis Example 4

144 g (1.0 mole) of 1-naphthol, 2.2 g (0.02 moles) of o-cresol, 400 g of methanol, 96 g of water, and 27.7 g (0.85 moles) of 92% paraformaldehyde were put into a 1 L four-neck flask provided with a thermometer, a cooling tube, and a stirrer. Subsequently, 4.8 g of an aqueous solution of paratoluenesulfonic acid having a concentration adjusted to 50% was added to the four-neck flask with stirring. The amount of water in the reaction system was 69.9 parts by mass with respect to 100 parts by mass of 1-naphthol. Thereafter, the temperature was raised to 60° C. while stirring the solution in the system, and the solution was allowed to react for 2 hours. During the reaction, the organic layer and the aqueous layer were in a “homogeneous” state in which the layers were fully compatible. After the reaction ended, 400 g of methyl isobutyl ketone was added thereto, the solution in the system was transferred to a separating funnel, and the aqueous layer was separated from the organic layer and removed. Next, after washing the resulting product with water until the washing water became neutral, the solvent was removed from the organic layer by heating under reduced pressure, whereby 149 g of a novolac resin (4) was obtained. When GPC and GC were performed on the novolac resin (4), the number average molecular weight (Mn) was 955, the weight average molecular weight (Mw) was 1427, the polydispersity (Mw/Mn) was 1.495, and the residual monomer amount was 2.52% by mass. The GPC chart of the novolac resin (4) is shown in FIG. 4.

### Synthesis Example 5

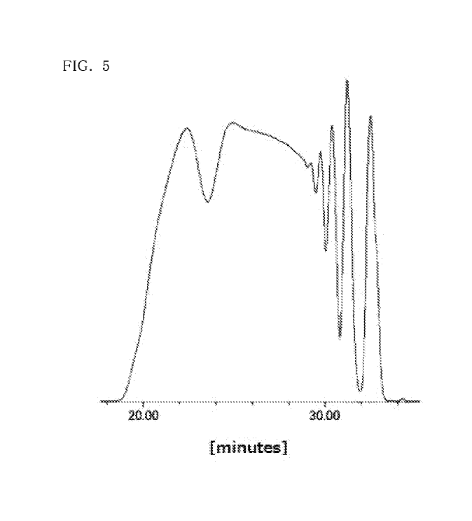

648 g (6 moles) of m-cresol, 432 g (4 moles) of p-cresol, 2.5 g (0.2 moles) of oxalic acid, and 492 g of 42% formaldehyde were put into a 2 L four-neck flask provided with a stirrer and a thermometer, then, the temperature was raised to 100° C., and the resulting product was allowed to react. After dehydration and distillation were performed on the solution in the system at 200° C. at normal pressure, distillation under reduced pressure was performed at 230° C. for 6 hours, whereby 736 g of a novolac resin (5) was obtained. When GPC and GC were performed on the novolac resin (5), the number average molecular weight (Mn) was 1450, the weight average molecular weight (Mw) was 10.316, the polydispersity (Mw/Mn) was 7.116, and the residual monomer amount was 0.12% by mass. The GPC chart of the novolac resin (5) is shown in FIG. 5.

### Examples 1 to 3 and Comparative Examples 1 and 2

With respect to each of the novolac resins (1) to (5) synthesized in Synthesis Examples 1 to 5, a resin component and a photosensitive agent (P-200 manufactured by Toyo Gosei Co. Ltd.), and propylene glycol monomethyl ether acetate (PGMEA) were mixed at a proportion of 16/4/80 (parts by mass), as shown in Table 1, to thereby be dissolved, and then filtration was performed through a 0.2 μm membrane filter, and the resulting product was used as a photosensitive composition (positive type resist composition).

Evaluations of alkali developing properties, sensitivity, resolution, heat resistance, water absorbency, and contamination properties were performed on each of the positive type photosensitive compositions obtained. The evaluation method is as follows.

<Alkali Developing Properties Evaluation>

The photosensitive composition was applied on a 5 inch silicon wafer by a spin coater so as to provide a thickness of about 1 μm, and dried for 60 seconds on a hot plate at 110° C. The obtained wafer was immersed in a developer (2.38% aqueous tetramethylammonium hydroxide solution) for 60 seconds, and dried for 60 seconds on a hot plate at 110° C. Before and after immersion in the developer, the thickness of the coating film of the photosensitive composition was measured, and the value obtained by dividing the difference in the thickness before and after immersion in the developer by 60 was designated as an alkali developing properties (ADR (angstrom/s)). In the case of being subjected to exposure, the wafer was subjected to 100 mJ/cm² irradiation to be sufficiently exposed by a ghi line lamp (a multilight manufactured by Ushio Inc.) and then subjected to Post Exposure Bake (PEB) under conditions of 140° C. and 60 seconds, and ADR measurement was performed on the resultant wafer.

<Sensitivity Evaluation>

In the case where a mask corresponding to resist patterns of 1 to 10 μm, which have a line-and-space of 1:1, was adhered to the wafer which the photosensitive composition had been applied on in a thickness of about 1 μm and been dried, the exposure amount at which the resist pattern of 3 μm can be faithfully reproduced with a ghi line lamp (Eop exposure amount) was determined.

<Resolution Evaluation>

A photo mask was placed on a silicon wafer to which a photosensitive composition had been applied and dried, and exposure was performed by 100 mJ/cm² irradiation using a ghi line lamp (a multilight manufactured by Ushio Inc.). The coating film after irradiation was developed and dried in the same manner as in the ADR measurement. The pattern state of the resist pattern on the wafer after development was evaluated using a laser microscope (VK-8500) manufactured by Keyence Corporation. One that can be resolved at the L/S each having 5 μm was designated as “A”, and one that cannot be resolved at the L/S each having 5 μm was designated as “B”.

<Heat Resistance Evaluation>

The photosensitive composition was applied on a 5 inch silicon wafer by a spin coater so as to provide a thickness of about 1 μm, and dried for 60 seconds on a hot plate at 110° C. The resin was scrapped from the obtained wafer to measure the Tg. In the measurement of Tg, scanning was performed using a differential calorimeter (differential scanning calorimetry (DSC) Q100 manufactured by TA Instruments) under conditions of a nitrogen atmosphere, a temperature range of −100° C. to 200° C., and a temperature-increase rate of 10° C./min, and the measurement results were used as a glass transition temperature (Tg).

<Water Absorbency Evaluation>

The photosensitive composition was applied on a 5 inch silicon wafer by a spin coater so as to provide a thickness of about 1 μm, and dried for 60 seconds on a hot plate at 110° C. Moisture was absorbed in the obtained wafer at 85° C. and a humidity of 85% for 24 hours, and the water absorption was calculated from the weight change.

<Contamination Properties Evaluation>

The photosensitive composition was applied on a 5 inch silicon wafer by a spin coater so as to provide a thickness of about 1 μm, and dried for 60 seconds on a hot plate at 110° C. The obtained wafer was cut into a size of 1 cm×1 cm, then, the obtained 5 pieces were sealed in a 10 mL transparent vial, and used as samples for evaluation. After each sample for evaluation was heated in an explosion-proof oven at 121° C. for 24 hours and then cooled to room temperature, haze due to sublimation components adhered to the vial glass surface was visually observed. The case where there was no haze visually observed was designated as “A”, and the case where there was haze was designated as “B”.

TABLE 1

| | Example | Example | Example | Comparative | Comparative |
|---|---|---|---|---|---|
| | 1 | 2 | 3 | Example 1 | Example 2 |
| Novolac resin (1) | 16 | — | — | — | — |
| Novolac resin (2) | — | 16 | — | — | — |
| Novolac resin (3) | — | — | 16 | — | — |
| Novolac resin (4) | — | — | — | 16 | — |
| Novolac resin (5) | — | — | — | — | 16 |
| Photosensitive agent | 4 | 4 | 4 | 4 | 4 |
| PGMEA | 80 | 80 | 80 | 80 | 80 |
| Total | 100 | 100 | 100 | 100 | 100 |

Evaluation

| | | | | | |
|---|---|---|---|---|---|
| ADR (angstrom/s) before exposure | 0 | 0 | 0 | 0 | 0 |
| after exposure | 1160 | 1130 | 1060 | 1250 | 470 |
| Sensitivity (mJ/cm²) | 40 | 40 | 40 | 40 | 80 |
| Resolution | A | A | A | A | B |
| Moisture absorptivity (% by weight) | 1.4 | 1.5 | 1.1 | 1.7 | 2.4 |
| Heat resistance (Tg) (° C.) | >200 | >200 | >200 | >200 | 110 |
| Contamination properties | A | A | A | B | A |

As a result, the coating film (Examples 1 to 3) formed of a photosensitive composition containing each of novolac resins (1) to (3) which were the hydroxynaphthalene novolac resins according to the present invention had good ADR after exposure of 1,000 angstrom/s or more, high sensitivity and resolution, low moisture absorption, a sufficiently high Tg of 200° C. or more, and good heat resistance. Furthermore, contamination properties were also low. In contrast, in the coating film (Comparative Example 1) formed of a photosensitive composition containing the novolac resin (4) in which the residual monomer amount was 2.52% by mass in terms of the solid content of the resin, the moisture absorption was somewhat low, ADR after exposure, the sensitivity, and the resolution were good as in Examples 1 to 3, but the antifouling properties were poor. On the other hand, in the coating film (Comparative Example 2) formed of a photosensitive composition containing the novolac resin (5) which has a cresol novolac resin structure as the main skeleton, the residual monomer amount was as small as 0.12% by mass, and thus, contamination properties were good, but all of ADR, sensitivity, moisture absorption, and heat resistance were poorer than in Examples 1 to 3.

### Examples 4 to 8 and Comparative Examples 3 and 5

With respect to each of the novolac resins (1) to (5) synthesized in Synthesis Examples 1 to 5, a resin component, a photosensitive agent (P-200 manufactured by Toyo Gosei Co. Ltd.), glycoluril, and propylene glycol monomethyl ether acetate (PGMEA) were mixed at a proportion (parts by mass) described in Tables 2 and 3 to thereby be dissolved, and filtration was performed through a 0.2 μm membrane filter, and the resulting product was used as a photosensitive composition (positive type resist composition).

Evaluations of alkali developing properties, sensitivity, resolution, heat resistance, water absorbency, and contamination properties were performed on each positive type photosensitive composition obtained. Evaluation methods of alkali developing properties, sensitivity, resolution, and water absorbency were performed in the same manner as in Example 1, and heat resistance and contamination properties were evaluated as follows.

<Heat Resistance Evaluation>

The photosensitive composition was applied on a 5 inch silicon wafer by a spin coater so as to provide a thickness of about 1 μm, dried, and cured by heating for 60 seconds on a hot plate at 230° C. The resin was scrapped from the obtained wafer to measure the Tg. In the measurement of Tg, scanning was performed using a differential calorimeter (differential scanning calorimetry (DSC) Q100 manufactured by TA Instruments) under conditions of a nitrogen atmosphere, a temperature range of −100° C. to 200° C., and a temperature-increase rate of 10° C./min, and the measurement result was used as a glass transition temperature (Tg).

<Contamination Properties Evaluation>

The photosensitive composition was applied on a 5 inch silicon wafer by a spin coater so as to provide a thickness of about 1 μm, dried, and cured by heating for 60 seconds on a hot plate at 230° C. The obtained wafer was cut into a size of 1 cm×1 cm, then, the obtained 5 pieces were sealed in a 10 mL transparent vial, and used as samples for evaluation. After each sample for evaluation was heated in an explosion-proof oven at 121° C. for 24 hours and then cooled to room temperature, haze due to sublimation components adhered to the vial glass surface was visually observed. The case where there was no haze visually observed was designated as “A”, and the case where there was haze was designated as “B”.

TABLE 2

| | Example | Example | Example | Example | Example |
|---|---|---|---|---|---|
| | 4 | 5 | 6 | 7 | 8 |
| Novolac resin (1) | 16 | — | — | 16 | 16 |
| Novolac resin (2) | — | 16 | — | — | — |
| Novolac resin (3) | — | — | 16 | — | — |
| Novolac resin (4) | — | — | — | — | — |
| Novolac resin (5) | — | — | — | — | — |
| Photosensitive agent | 3 | 3 | 3 | 3 | 3 |
| Glycoluril | 1 | 1 | 1 | 5 | 8 |
| PGMEA | 80 | 80 | 80 | 80 | 80 |
| Total | 100 | 100 | 100 | 108 | 111 |

Evaluation

| | | | | | |
|---|---|---|---|---|---|
| ADR (angstrom/s) before exposure | 0 | 0 | 0 | 0 | 0 |
| after exposure | 1120 | 1100 | 1030 | 780 | 500 |
| Sensitivity (mJ/cm²) | 40 | 40 | 40 | 50 | 60 |
| Resolution | A | A | A | A | A |
| Moisture absorptivity (% by weight) | 1.4 | 1.5 | 1.1 | 1.5 | 1.6 |
| Heat resistance (Tg) (° C.) | >250 | >250 | >250 | >250 | >250 |
| Contamination properties | A | A | A | A | A |

TABLE 3

| | Compar- | Compar- | Compar- |
|---|---|---|---|
| | ative | ative | ative |
| | Example 3 | Example 4 | Example 5 |
| Novolac resin (1) | — | — | 16 |
| Novolac resin (2) | — | — | — |
| Novolac resin (3) | — | — | — |
| Novolac resin (4) | 16 | — | — |
| Novolac resin (5) | — | 16 | — |
| Photosensitive agent | 3 | 3 | 3 |
| Glycoluril | 1 | 1 | 10 |
| PGMEA | 80 | 80 | 80 |
| Total | 100 | 100 | 193 |

Evaluation

| | | | |
|---|---|---|---|
| ADR (angstrom/s) before exposure | 0 | 0 | 0 |
| after exposure | 1250 | 470 | 180 |
| Sensitivity (mJ/cm²) | 40 | 80 | 80 |
| Resolution | A | B | B |
| Moisture absorptivity (% by weight) | 1.7 | 2.4 | 1.8 |
| Heat resistance (Tg) (° C.) | >250 | >250 | >250 |
| Contamination properties | B | A | A |

From the results of Examples 4 to 6 in which the content of glycoluril which is a curing agent with respect to 100 parts by mass of the hydroxynaphthalene novolac resin was about 6 parts by mass, Example 7 in which the content was about 30 parts by mass, Example 8 in which the content was about 50 parts by mass, and Comparative Example 5 in which the content was about 60 parts by mass, it was confirmed that heat resistance is significantly improved by blending a curing agent therein. On the other hand, with the increase of the blending amount of a curing agent, the ADR value after exposure was decreased, and the moisture absorptivity was increased. In particular, in Comparative Example 5, the ADR value after exposure was rapidly decreased to 180, and the moisture absorptivity was also increased to 1.8. That is, in Comparative Example 5, a problem occurred in developing properties, and the composition was not suitable as a photosensitive material for permanent films.

From these results, it was found that by incorporating a curing agent in an amount of 0.1 to 50 parts by mass with respect to 100 parts by mass of the hydroxynaphthalene novolac resin according to the present invention, a photosensitive composition which has not only excellent moisture absorption resistance and a function of alkali developing properties, but also particularly excellent heat resistance, and is therefore suitable for use as permanent films, is obtained. In particular, it was found that by incorporating a curing agent in an amount of 0.1 to 30 parts by mass with respect to 100 parts by mass of the hydroxynaphthalene novolac resin according to the present invention, a photosensitive composition for permanent films which has high sensitivity, as well as a function of alkali developing properties and excellent heat resistance, is obtained (refer to Examples 4 and 7).

1. A photosensitive composition for permanent films, comprising:
a hydroxynaphthalene novolac resin having a structural portion (I) represented by the following General Formula (1) as a repeating unit and containing a hydroxynaphthalene (A) represented by the following General Formula (2) in an amount of 2% by mass or less in terms of the solid content of the resin,
provided that the photosensitive composition does not contain a curing agent, or contains a curing agent in an amount of 50 parts by mass or less with respect to 100 parts by mass of the hydroxynaphthalene novolac resin: 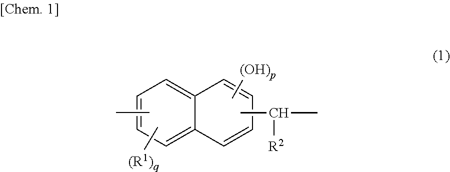
wherein R¹ represents a hydrogen atom, an alkyl group, an alkoxy group, an aryl group which may have a substituent, an aralkyl group which may have a substituent, or a halogen atom, a plurality of R¹'s may be the same as or different from each other,
R² represents a hydrogen atom, an alkyl group which may have a substituent, or an aryl group which may have a substituent,
p represents 1 or 2, and
q represents 4 or 5,
with the proviso that the sum of p and q is 6: 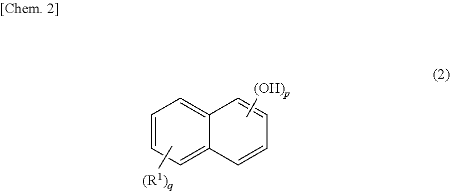
wherein R¹, p, and q are as defined in General Formula (1).

2. The photosensitive composition for permanent films according to claim 1, comprising:
a curing agent in an amount of 0.1 to 30 parts by mass with respect to 100 parts by mass of the hydroxynaphthalene novolac resin.

3. The photosensitive composition for permanent films according to claim 1,
wherein the hydroxynaphthalene novolac resin is obtained by reacting the hydroxynaphthalene (A) represented by General Formula (2) with the aldehyde (B) represented by General Formula (3) in the presence of an acid catalyst, in a system containing an organic solvent and 30 to 300 parts by mass of water with respect to 100 parts by mass of the hydroxynaphthalene (A), under the condition where the reaction proportion of (A)/(B) by a molar ratio is in a range of 0.5 to 1.5:
[Chem. 3]
R²—CHO (3)
wherein R² is as defined in General Formula (1).

4. (canceled)

5. The photosensitive composition for permanent films according to claim 1,
wherein R² is a hydrogen atom.

6. The photosensitive composition for permanent films according to claim 1,
further comprising:
a photosensitive agent.

7.-11. (canceled)

12. A permanent film formed of the photosensitive composition for permanent films according to claim 6.

13. The photosensitive composition for permanent films according to claim 2, further comprising:
a photosensitive agent.

14. The photosensitive composition for permanent films according to claim 3, further comprising:
a photosensitive agent.

15. A permanent film formed of the photosensitive composition for permanent films according to claim 13.

16. A permanent film formed of the photosensitive composition for permanent films according to claim 14.
